(19) United States
(12) Patent Application Publication
(10) Pub. No.: US 2026/0033026 A1
(43) Pub. Date: Jan. 29, 2026

(54) PHOTODETECTION DEVICE AND RANGING SYSTEM

(71) Applicant: SONY SEMICONDUCTOR SOLUTIONS CORPORATION, KANAGAWA (JP)

(72) Inventors: YUSUKE MATSUMURA, KANAGAWA (JP); TATSUYA NAKATA, KANAGAWA (JP); WATARU ONISHI, KANAGAWA (JP)

(21) Appl. No.: 18/995,190

(22) PCT Filed: Jul. 12, 2023
(86) PCT No.: PCT/JP2023/025775

§ 371 Date: Jan. 16, 2025

(30) Foreign Application Priority Data
Jul. 29, 2022 (JP) 2022-122172

(51) Int. Cl. H10F 39/00; G01S 7/481; G01S 17/894; G01S 17/931

(52) U.S. Cl. CPC H10F 39/8057; G01S 7/4816; G01S 17/894; G01S 17/931; H10F 39/8063; H10F 39/807; H10F 39/809; H10F 39/811

(57) ABSTRACT

A photodetection device according to one embodiment of the present disclosure includes: a first semiconductor layer including a light-receiving element configured to receive light and output a current; a trench provided in the first semiconductor layer, the trench surrounding the light-receiving element; a light-shielding film provided in the trench, the light-shielding film including a metal material; and a first wiring provided on a first surface side of the first semiconductor layer. The light-receiving element includes a first semiconductor region of first conductivity type and a second semiconductor region of second conductivity type that are provided on the first surface side of the first semiconductor layer. The first wiring includes polycrystalline silicon or amorphous silicon and electrically connects the first semiconductor region and the light-shielding film.

### TECHNICAL FIELD

The present disclosure relates to a photodetection device and to a ranging system.

### BACKGROUND ART

A device is proposed that includes a plurality of pixels including a single photon avalanche diode (SPAD) element and that performs photodetection (Patent Literature 1).

### CITATION LIST

### Patent Literature

Patent Literature 1: Japanese Unexamined Patent Application Publication No. 2021-34559

### SUMMARY OF THE INVENTION

Photodetection devices are desired to suppress an increase in power consumption.

It is desired to provide a photodetection device that makes it possible to reduce power consumption.

A photodetection device according to one embodiment of the present disclosure includes: a first semiconductor layer including a light-receiving element configured to receive light and output a current; a trench provided in the first semiconductor layer, the trench surrounding the light-receiving element; a light-shielding film provided in the trench, the light-shielding film including a metal material; and a first wiring provided on a first surface side of the first semiconductor layer. The light-receiving element includes a first semiconductor region of first conductivity type and a second semiconductor region of second conductivity type that are provided on the first surface side of the first semiconductor layer. The first wiring includes polycrystalline silicon or amorphous silicon and electrically connects the first semiconductor region and the light-shielding film.

A ranging system according to one embodiment of the present disclosure includes: a light source configured to apply light to a target object; and a photodetection device that receives light from the target object. The photodetection device includes: a first semiconductor layer including a light-receiving element configured to receive light and output a current; a trench provided in the first semiconductor layer, the trench surrounding the light-receiving element; a light-shielding film provided in the trench, the light-shielding film including a metal material; and a first wiring provided on a first surface side of the first semiconductor layer. The light-receiving element includes a first semiconductor region of first conductivity type and a second semiconductor region of second conductivity type that are provided on the first surface side of the first semiconductor layer. The first wiring includes polycrystalline silicon or amorphous silicon and electrically connects the first semiconductor region and the light-shielding film.

### BRIEF DESCRIPTION OF THE DRAWINGS

FIG. 1 is a diagram illustrating an example of a schematic configuration of a photodetection device according to an embodiment of the present disclosure.

FIG. 2 is a diagram illustrating a configuration example of the photodetection device according to the embodiment of the present disclosure.

FIG. 3A is a diagram illustrating a configuration example of a pixel of the photodetection device according to the embodiment of the present disclosure.

FIG. 3B is a diagram illustrating another configuration example of the pixel of the photodetection device according to the embodiment of the present disclosure.

FIG. 4A is a diagram for describing an example of a cross-sectional configuration of the pixel of the photodetection device according to the embodiment of the present disclosure.

FIG. 4B is a diagram for describing an example of a plan configuration of the pixel of the photodetection device according to the embodiment of the present disclosure.

FIG. 5A is a diagram illustrating an example of a cross-sectional configuration of the photodetection device according to the embodiment of the present disclosure.

FIG. 5B is a diagram illustrating an example of a plan configuration of the photodetection device according to the embodiment of the present disclosure.

FIG. 6 is a diagram illustrating another example of the cross-sectional configuration of the photodetection device according to the embodiment of the present disclosure.

FIG. 7 is a diagram illustrating an example of a schematic configuration of a ranging system according to an embodiment of the present disclosure.

FIG. 8 is a diagram for describing an example of a plan configuration of a pixel of a photodetection device according to Modification 1 of the present disclosure.

FIG. 9 is a diagram for describing an example of a cross-sectional configuration of a pixel of a photodetection device according to Modification 2 of the present disclosure.

FIG. 10 is a diagram for describing an example of a cross-sectional configuration of a pixel of a photodetection device according to Modification 3 of the present disclosure.

FIG. 11 is a block diagram depicting an example of schematic configuration of a vehicle control system.

FIG. 12 is a diagram of assistance in explaining an example of installation positions of an outside-vehicle information detecting section and an imaging section.

FIG. 13 is a view depicting an example of a schematic configuration of an endoscopic surgery system.

FIG. 14 is a block diagram depicting an example of a functional configuration of a camera head and a camera control unit (CCU).

### MODES FOR CARRYING OUT THE INVENTION

Hereinafter, an embodiment of the present disclosure will be described in detail with reference to the drawings. Note that the description will be given in the following order.
1. Embodiments
2. Modifications
3. Examples of Use
4. Applications

### 1. Embodiments

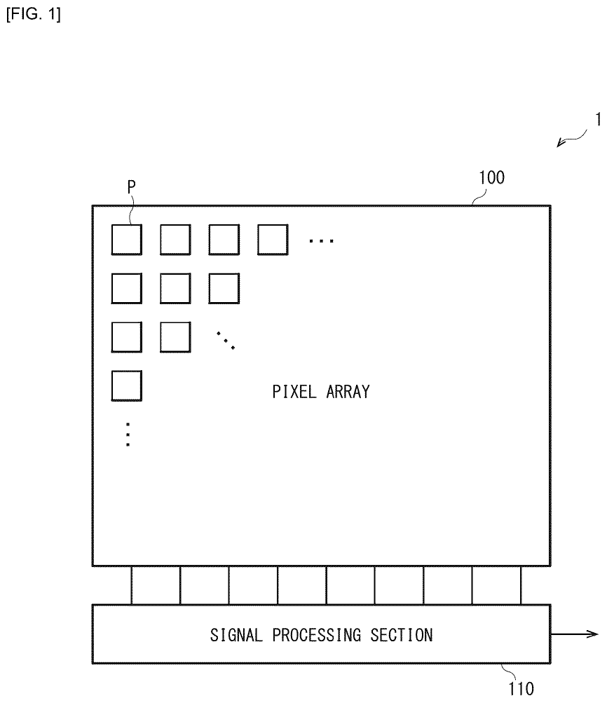

FIG. 1 is a diagram illustrating an example of a schematic configuration of a photodetection device according to an embodiment of the present disclosure. A photodetection device 1 is a device configured to detect incident light. The photodetection device 1 includes a plurality of pixels P each including a light-receiving element. The photodetection device 1 is configured to photoelectrically convert incident light to generate a signal. The photodetection device 1 may be used for a ranging sensor, an image sensor, or the like.

The photodetection device 1 includes, for example, a ranging sensor configured to perform distance measurement of TOF (Time Of Flight) scheme. Note that the photodetection device 1 may be used as a sensor configured to detect an event, for example, an event-driven sensor (which is referred to as EVS (Event Vision Sensor), EDS (Event Driven Sensor), DVS (Dynamic Vision Sensor), or the like).

In the example illustrated in FIG. 1, the photodetection device 1 includes, as a pixel array 100, a region including the plurality of pixels P arranged two-dimensionally. The pixel array 100 is a pixel section with the pixels P arranged in a matrix. The light-receiving element of each pixel P includes, for example, an avalanche photo diode (APD) element.

The pixel P includes an SPAD element as the light-receiving element (light receiver), for example. The photodetection device 1 captures incident light (image light) from an object to be measured, via an optical system (not illustrated in FIG. 1) including an optical lens. The light-receiving element may receive light and generate an electric charge by photoelectric conversion, and generate an optical current.

The photodetection device 1 includes a signal processing section 110 configured to perform signal processing. The signal processing section 110, being a signal processing circuit, performs signal processing (information processing). The signal processing section 110 performs variety of types of signal processing on a signal of each pixel and outputs the signal of the pixel after the signal processing.

The signal processing section 110, also serving as a control section, is configured to control each sections in the photodetection device 1. The signal processing section 110 includes, for example, a plurality of logic circuits. As an example, the signal processing section 110 includes a plurality of logic circuits, the logic circuits including a timing generator that generates variety of types of timing signals, a shift register, an address decoder, and a memory. The signal processing section 110 may supply, to each pixel P, a signal for the pixel P to be driven, and control an operation of each pixel P.

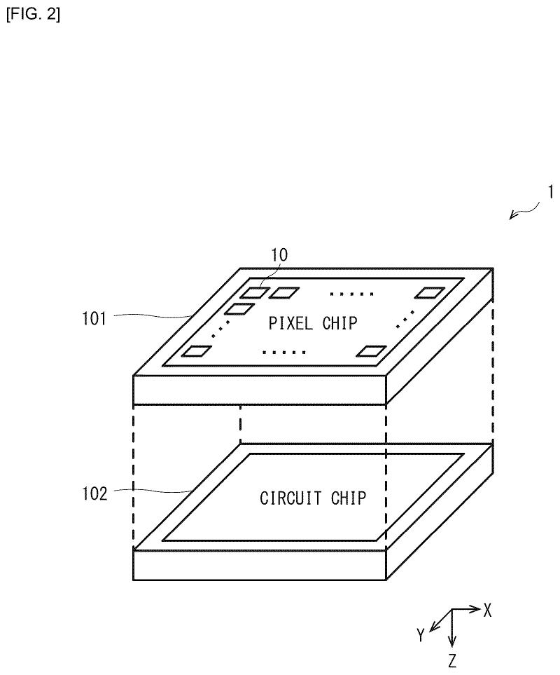

FIG. 2 is a diagram illustrating a configuration example of the photodetection device according to the embodiment. As illustrated in FIG. 2, the photodetection device 1 includes a first semiconductor chip (which is referred to as a pixel chip 101) and a second semiconductor chip (which is referred to as a circuit chip 102). The pixel chip 101 and the circuit chip 102 are stacked overlapping with each other.

The photodetection device 1 has a structure (stacked structure) where the pixel chip 101 and the circuit chip 102 are stacked in a Z axis direction. Note that, as illustrated in FIG. 2, an incident direction of light from a subject as an object to be measured is assumed as the Z axis direction, a lateral direction of the paper sheet orthogonal to the Z axis direction is assumed as an X axis direction, and a direction orthogonal to the Z axis and X axis is assumed as a Y axis direction. Hereinafter, in the drawings, a direction may be described based on the directions of arrows in FIG. 2 as references.

The pixel chip 101 is provided with a light-receiving element 10 of each pixel P of the pixel array 100. In the pixel chip 101, a plurality of the light-receiving elements 10 is arranged in a horizontal direction (row direction) being a first direction and in a vertical direction (column direction) being a second direction orthogonal to the first direction. The circuit chip 102 is provided with, for example, the signal processing section 110 described above.

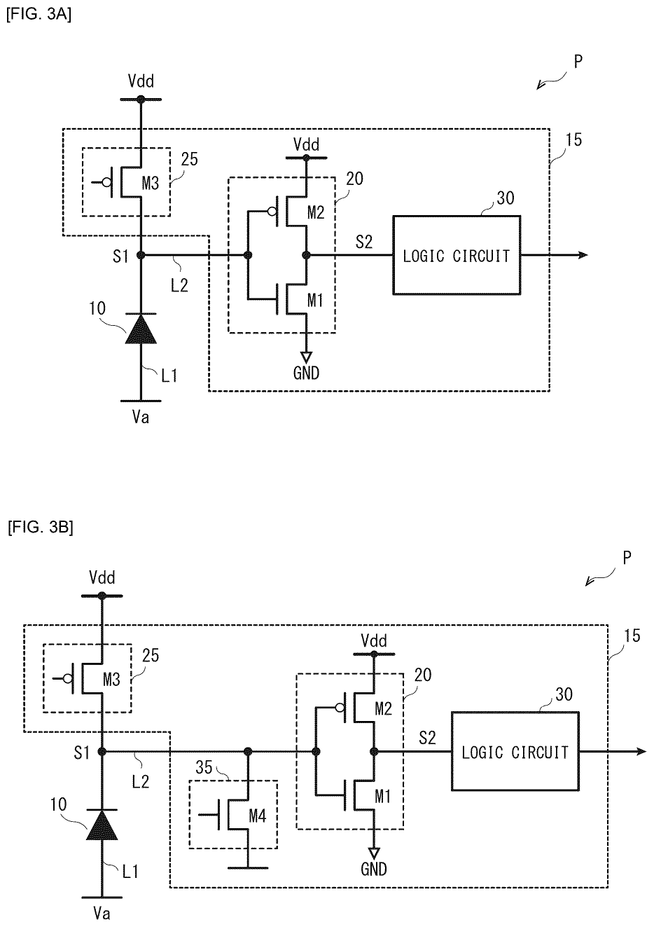

FIG. 3A is a diagram illustrating a configuration example of the pixel of the photodetection device according to the embodiment. The pixel P of the photodetection device 1 includes the light-receiving element 10 and a reading circuit 15. The reading circuit 15 is configured to output a signal based on a current of the light-receiving element 10. The reading circuit 15 includes a circuit for a signal based on an optical current flowing through the light-receiving element 10 to be read out, for example, a generation unit 20, a supply unit 25, and a logic circuit 30.

The light-receiving element 10 is configured to receive light and generate a signal. The light-receiving element 10, being an SPAD element, includes a breakdown region (breakdown portion) allowing avalanche breakdown, as to be described below. The light-receiving element 10 may convert an entered photon into an electric charge and output a signal S1 being an electric signal corresponding to the entered photon. Note that the light-receiving element 10 may also be referred to as a photoelectric conversion element (photoelectric converter) configured to photoelectrically convert light.

The light-receiving element 10 is electrically connected to, for example, a power supply line, an electrode, or the like configured to supply a predetermined voltage. In the example illustrated in FIG. 3A, the light-receiving element 10 has an anode as one electrode electrically connected to a wiring (anode wiring L1 in FIG. 3A), an electrode, or the like supplied with a power supply voltage. The anode of the light-receiving element 10 is supplied with a power supply voltage (anode voltage Va in FIG. 3A), via the anode wiring L1, from a power supply (voltage source) configured to supply a voltage (current), for example. The light-receiving element 10 has a cathode as another electrode electrically connected, via the supply unit 25, to a wiring, an electrode, or the like supplied with a power supply voltage Vdd.

Between the cathode and anode of the light-receiving element 10, with a voltage supplied via the supply unit 25, a voltage having a potential difference greater than a breakdown voltage of the light-receiving element 10 may be applied. In other words, a potential difference between both end of the light-receiving element 10 may be set as a potential difference greater than the breakdown voltage. In a case where a reverse bias voltage higher than the breakdown voltage is supplied, the light-receiving element 10 is brought into a state operable in a Geiger mode. The light-receiving element 10 in the Geiger mode may cause avalanche breakdown phenomenon upon entrance of a photon and generate a current in a pulse form. In the pixel P, the signal S1 depending on an optical current flowing through the light-receiving element 10 caused by entrance of a photon is output to the generation unit 20.

The generation unit 20 is configured to generate a signal S2 based on the signal S1 generated by the light-receiving element 10. In the example illustrated in FIG. 3A, the generation unit 20 includes an inverter. The generation unit 20 includes a transistor M1 and a transistor M2 connected in series. The transistor M1 and the transistor M2 are each an MOS transistor (MOSFET) having terminals of gate, source, and drain. The transistor M1 is an NMOS transistor and the transistor M2 is a PMOS transistor.

An input portion of the generation unit 20 is electrically connected to the cathode of the light-receiving element 10 and to the supply unit 25. An output portion of the generation unit 20 is electrically connected to the logic circuit 30. The input portion of the generation unit 20 is electrically connected to a wiring (cathode wiring L2 in FIG. 3) connecting the light-receiving element 10 and the supply unit 25.

The generation unit 20 receives the signal SI from the light-receiving element 10. A signal level of the signal S1, that is a voltage (potential) of the signal S1, varies depending on a current flowing through the light-receiving element 10. For example, in a case where a voltage of the signal S1 is higher than a threshold, the generation unit 20 outputs the signal S2 of low level. Further, in a case where the voltage of the signal S1 is lower than the threshold, the generation unit 20 outputs the signal S2 of high level. The generation unit 20 may output, to the logic circuit 30, the signal S2 serving as a pulse signal based on the voltage of the signal S1.

In the example illustrated in FIG. 3A, when the voltage of the signal S1 is made lower than a threshold voltage of the inverter being the generation unit 20 due to reception of a photon by the light-receiving element 10, the inverter causes the voltage of the signal S2 to be in the high level from the low level. Note that the generation unit 20 may include a buffer circuit and an AND circuit.

The supply unit 25 is configured to supply a voltage and current to the light-receiving element 10. The supply unit 25 is electrically connected to a power supply line supplied with the power supply voltage Vdd, allowing a voltage and current to be supplied to the light-receiving element 10. In the example illustrated in FIG. 3A, the supply unit 25 includes a transistor M3. The transistor M3 is, for example, a PMOS transistor. Note that the supply unit 25 may include a resistance element.

In a case where avalanche breakdown occurs and the potential difference between the electrodes of the light-receiving element 10 is smaller than the breakdown voltage, the supply unit 25 may supply a current to the light-receiving element 10. The supply unit 25 performs recharge of the light-receiving element 10 to bring the light-receiving element 10 into the state operable in the Geiger mode again. The supply unit 25 is a recharge unit and may also be said to recharge the light-receiving element 10 with an electric charge and recharge a voltage of the light-receiving element 10. Further, the supply unit 25 is also referred to as a quench unit (quench circuit).

As described above, when a photon enters the light-receiving element 10 and avalanche breakdown occurs, the current flowing through the light-receiving element 10 increases, causing the potential difference between the cathode and anode of the light-receiving element 10 to be smaller. In the example illustrated in FIG. 3A, a cathode voltage of the light-receiving element 10 lowers and the voltage of the signal S1 to be input to the generation unit 20 lowers. With the potential difference between the electrodes of the light-receiving element 10 made smaller than the breakdown voltage, avalanche breakdown is quenched. With a fall in the voltage of the signal S1, the generation unit 20 causes the voltage of the signal S2 to be in the high level from the low level.

When a current (recharge current) from the supply unit 25 is supplied to the light-receiving element 10, the potential difference between the electrodes of the light-receiving element 10 is made greater. In the example illustrated in FIG. 3A, the cathode voltage of the light-receiving element 10, that is the voltage of the signal S1, rises. With the potential difference between the electrodes of the light-receiving element 10 made greater than the breakdown voltage, the light-receiving element 10 is brought into the state operable in the Geiger mode again. With a rise in the voltage of the signal S1, the generation unit 20 causes the voltage of the signal S2 to be in the low level from the high level. As described above, the generation unit 20 may output, to the logic circuit 30, the signal S2 serving as the pulse signal based on the voltage of the signal S1.

The logic circuit 30 includes a counter circuit and a TDC (Time to Digital Converter) circuit. For example, the logic circuit 30 is configured to perform counting (enumeration) depending on a signal input. The logic circuit 30 may count pulses of the signal S2, generate a signal based on the number of pulses of the signal S2 and the pulse width, and output the signal to the signal processing section 110. Note that the logic circuit 30 may include a circuit that controls the supply unit 25.

FIG. 3B is a diagram illustrating another configuration example of the pixel of the photodetection device according to the embodiment. The reading circuit 15 may include an output control unit 35 as illustrated in FIG. 3B. The output control unit 35 includes a transistor M4. The output control unit 35 is electrically connected to the wiring (cathode wiring L2 in FIG. 3) connecting the light-receiving element 10 and the supply unit 25. The transistor M4 is, for example, an NMOS transistor.

The output control unit 35 is configured to control output of a signal of the light-receiving element 10. The output control unit 35 may be controlled by a signal input to a gate of the output control unit 35 and may control a reading timing of the signal of the light-receiving element 10. For example, in a case where the transistor M4 of the output control unit 35 is in an off state, the signal S1 depending on reception of a photon is possible to be output to the generation unit 20. Note that the output control unit 35 may also be said a selection unit configured to select which pixel P to be read.

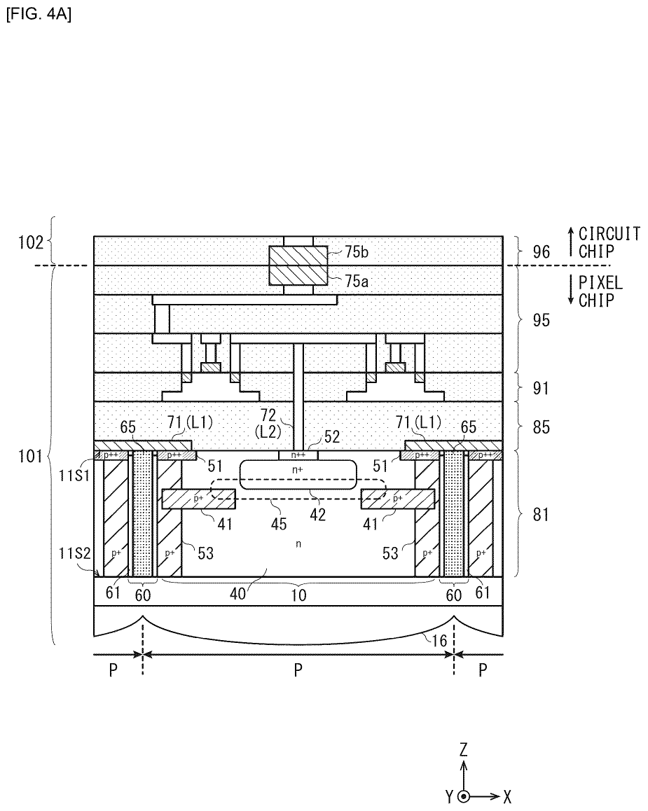

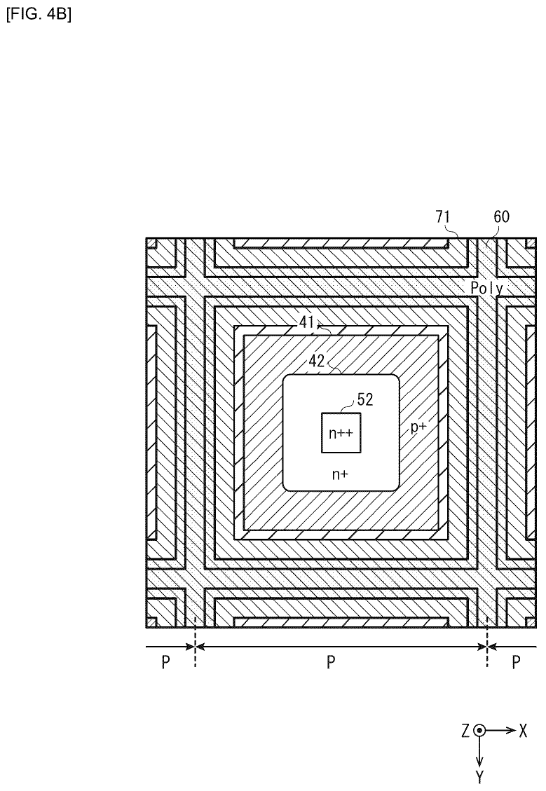

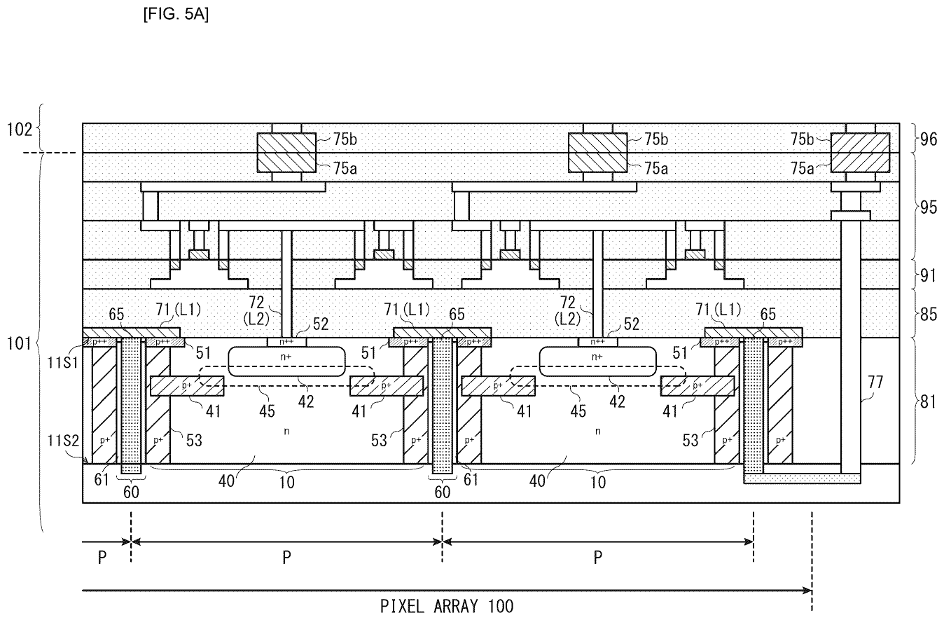

FIG. 4A is a diagram for describing an example of a cross-sectional configuration of the pixel of the photodetection device according to the embodiment. FIG. 4B is a diagram for describing an example of a plan configuration of the pixel of the photodetection device according to the embodiment. The photodetection device 1 includes the pixel chip 101 and the circuit chip 102 as described above. The pixel chip 101 and the circuit chip 102 each include a semiconductor substrate (for example, silicon substrate or SOI (Silicon On Insulator) substrate).

As illustrated in FIG. 4A, the pixel chip 101 includes a first semiconductor layer 81, a first insulating layer 85, a second semiconductor layer 91, and a second insulating layer 95. The pixel chip 101 has a configuration where the first semiconductor layer 81, the first insulating layer 85, the second semiconductor layer 91, and the second insulating layer 95 are stacked in the Z axis direction. The first insulating layer 85 and second insulating layer 95 each include a single layer film including one type out of, for example, an oxide film (for example, silicon oxide film), a nitride film (for example, silicon nitride film), an oxynitride film, and the like, or include a laminated film including two or more types out of them.

As illustrated in FIG. 4A, the first semiconductor layer 81 includes a first surface 11S1 and a second surface 11S2 opposed to each other. The insulating layer 85 is provided on the first surface 11S1 side of the first semiconductor layer 81. A lens section 16 is provided on the second surface 11S2 side of the first semiconductor layer 81. This may also be said as that the lens section 16 is provided on a side that light from an optical lens system enters and the first insulating layer 85 is provided on a side opposite to the side that the light enters.

The pixel chip 101 is provided with the plurality of pixels P each including the light-receiving element 10. On the second surface 11S2 side of the first semiconductor layer 81, the lens section 16 or the like that collects light is provided, for example, for each pixel P. The lens section 16 is an optical member also called an on-chip lens.

Note that, on the second surface 11S2 side of the first semiconductor layer 81, a filter may be provided configured to cause light in a specific wavelength region of incident light to selectively penetrate. Examples of the filter include a RGB color filter, a complementary color filter, and a filter for infrared light to penetrate. The filter is provided between the lens section 16 and the first semiconductor layer 81.

As illustrated in FIG. 4A, the first semiconductor layer 81 includes semiconductor regions 40, 41, and 42 and semiconductor regions 51, 52, and 53. The semiconductor region 41 and semiconductor region 42 are provided for each pixel P. The semiconductor region 40 is provided around the semiconductor region 41 and semiconductor region 42. This may also be said as that the semiconductor region 41 and semiconductor region 42 are disposed taking the place of a portion of the semiconductor region 40. The semiconductor region 41 has a conductivity type different from that of the semiconductor region 42, and vice versa.

For example, the semiconductor region 41 is a p-type semiconductor region and is a semiconductor layer formed using a p-type impurity. The semiconductor region 41 is a p-type diffusion region and may also be said a p-type conductive layer. Further, the semiconductor region 42 is an n-type semiconductor region and is a semiconductor layer formed using an n-type impurity. The semiconductor region 42 is an n-type diffusion region and may also be said an n-type conductive layer.

In the example illustrated in FIGS. 4A and 4B, the p-type semiconductor region 41 has an impurity concentration higher than an impurity concentration of the semiconductor region 40 and thus serves as a (p+)-type semiconductor region. Further, the n-type semiconductor region 42 has an impurity concentration higher than an impurity concentration of the semiconductor region 40 and thus serves as an (n+)-type semiconductor region.

The light-receiving element 10 includes the p-type semiconductor region 41 and n-type semiconductor region 42, and includes a breakdown region 45 (breakdown portion) allowing avalanche breakdown, as schematically illustrated in FIG. 4A. The pixel P may also be said as a breakdown pixel including the breakdown region 45. The breakdown region 45 includes the p-type semiconductor region 41 and n-type semiconductor region 42. The semiconductor region 40 may photoelectrically convert incident light to generate an electric charge and transfer the electric charge to the breakdown region 45 side. The semiconductor region 40 is, for example, an n-type semiconductor region.

The semiconductor region 51 and semiconductor region 52 in the first semiconductor layer 81 are provided for each pixel P. The semiconductor region 51 and semiconductor region 52 are provided on the first surface 11S1 side of the first semiconductor layer 81. The semiconductor region 51 and semiconductor region 52 are located adjacent to the first surface 11S1 of the first semiconductor layer 81. The semiconductor region 51 has a conductivity type different from that of the semiconductor region 52, and vice versa.

In the first semiconductor layer 81, the semiconductor region 51 and semiconductor region 52 are formed for each pixel P, along the first surface 11S1 of the first semiconductor layer 81. At least a portion of the semiconductor region 51 is provided up to the first surface 11S1 (end surface) of the first semiconductor layer 81. Further, at least a portion of the semiconductor region 52 is provided up to the first surface 11S1 of the first semiconductor layer 81.

For example, the semiconductor region 51 is a p-type semiconductor region and is a semiconductor layer formed using a p-type impurity. The semiconductor region 51 is a p-type diffusion region and may also be said a p-type conductive layer. Further, the semiconductor region 52 is an n-type semiconductor region and is a semiconductor layer formed using an n-type impurity. The semiconductor region 52 is an n-type diffusion region and may also be said an n-type conductive layer.

In the example illustrated in FIGS. 4A and 4B, the p-type semiconductor region 51 has an impurity concentration higher than the impurity concentration of the p-type semiconductor region 41 and thus serves as a (p++)-type semiconductor region. Further, the n-type semiconductor region 52 has an impurity concentration higher than the impurity concentration of the n-type semiconductor region 42 and thus serves as an (n++)-type semiconductor region.

The p-type semiconductor region 51 is provided on the semiconductor region 53 of p-type, in contact with the p-type semiconductor region 53. The p-type semiconductor region 51 is electrically connected to the p-type semiconductor region 41 via the p-type semiconductor region 53. The p-type semiconductor region 41, the p-type semiconductor region 51, and the like are anode regions of the light-receiving element. The p-type semiconductor region 51 is an anode electrode and may also be said a contact region.

The n-type semiconductor region 52 is provided on the n-type semiconductor region 42, in contact with the n-type semiconductor region 42. The n-type semiconductor region 52 is electrically connected to the n-type semiconductor region 42. The n-type semiconductor region 42, the n-type semiconductor region 52, and the like are cathode regions of the light-receiving element. The n-type semiconductor region 52 is a cathode electrode and may also be said a contact region. The p-type semiconductor region 51 and n-type semiconductor region 52 being the contact regions respectively include a (p++)-type semiconductor region and (n++)-type semiconductor region, reducing a contact resistance.

A separation section 60 illustrated in FIG. 4A is provided between adjacent light-receiving elements 10, separating the light-receiving elements 10. The separation section 60 has a trench structure being provided at a boundary between adjacent pixels P (or light-receiving elements 10), and may also be said an inter-pixel separation section or an inter-pixel separation wall. In the example illustrated in FIG. 4A, the separation section 60 is provided penetrating through the first semiconductor layer 81.

The separation section 60 includes a trench 61 (ditch) and a light-shielding film 65. In the first semiconductor layer 81, the trench 61 is provided surrounding the light-receiving element 10. In the trench 61, the light-shielding film 65 including a metal material is provided. The trench 61 (ditch) is formed between adjacent light-receiving elements 10 and the light-shielding film 65, a metal film, is embedded in the trench 61. Note that, in the separation section 60, an insulating film may be formed covering an inside surface of the trench 61.

As the example illustrated in FIGS. 4A and 4B, the separation section 60 is provided surrounding the light-receiving element 10. The separation section 60 is formed in a grid-like shape, and thus disposed at a boundary between two adjacent pixels P (or light-receiving elements 10). The plurality of light-receiving elements 10 in the photodetection device 1 is electrically insulated from each other by the separation section 60. This may also be said as that the light-receiving elements 10 are provided sectioned by the separation section 60.

The light-shielding film 65 (light-shielding section) includes a member that blocks light. The light-shielding film 65 includes a metal material that blocks light, such as aluminum (Al), tungsten (W), titanium (Ti), cobalt (Co), hafnium (Hf), or tantalum (Ta), for example.

The light-shielding film 65 is located between adjacent light-receiving elements 10, suppressing leakage of light into surrounding pixels P. In the photodetection device 1, with the light-shielding film 65 provided, leakage of light into surrounding pixels P is suppressed, allowing mixing of colors to be suppressed. Note that the light-shielding film 65 may include a material that absorbs light.

The semiconductor region 53 is a p-type semiconductor region and is a semiconductor layer formed using a p-type impurity. The semiconductor region 53 is provided between the semiconductor region 40 and the separation section 60, suppressing occurrence of a dark current. In the example illustrated in FIGS. 4A and 4B, the p-type semiconductor region 53 has an impurity concentration higher than the impurity concentration of the semiconductor region 40 and thus serves as a (p+)-type semiconductor region. The p-type semiconductor region 53 is disposed along an outer periphery of the separation section 60 and is electrically connected to the p-type semiconductor region 51.

The pixel P of the light-receiving element 1 includes a first wiring 71 and a second wiring 72, as illustrated in FIG. 4A. The first wiring 71 is a wiring including polycrystalline silicon and is provided on the first surface 11S1 side of the first semiconductor layer 81. Note that the first wiring 71 may include amorphous silicon.

In the example illustrated in FIG. 4A, the first wiring 71 is disposed on the first surface 11S1 of the first semiconductor layer 81 and is located on the semiconductor region 51 and separation section 60. On the first surface 11S1 side of the first semiconductor layer 81, the first wiring 71 is provided covering the semiconductor region 51 and the separation section 60 including the light-shielding film 65. As illustrated in FIGS. 4A and 4B, the first wiring 71 is formed surrounding the light-receiving element 10.

The first wiring 71 is configured to electrically connect the p-type semiconductor region 51, being an anode electrode, and the light-shielding film 65. In the example illustrated in FIG. 4A, the first wiring 71 is directly connect with the p-type semiconductor region 51 and light-shielding film 65. The first wiring 71 may also be said a portion of the anode wiring L1 described above. In the example illustrated in FIG. 4A, no wiring is provided between the first wiring 71 and the second semiconductor layer 91. An upper portion of the first wiring 71 is covered with an insulating film.

The first wiring 71 is formed in a grid-like shape as illustrated in FIGS. 4A and 4B and is connected in common to the p-type semiconductor region 51 and the light-shielding film 65 of each of the plurality of pixels P. The first wiring 71 serves as a wiring shared by the plurality of pixels P.

The first semiconductor layer 81 and second semiconductor layer 91 illustrated in FIG. 4A are disposed sandwiching the first insulating layer 85. The second semiconductor layer 91 is provided with at least a portion of the reading circuit 15 described above. For example, the second semiconductor layer 91 includes an element formation region in an island-like shape as the example illustrated in FIG. 4A. For example, in the second semiconductor layer 91, a transistor of the generation unit 20, a transistor of the supply unit 25, a transistor of the output control unit 35, and the like may be disposed. A portion of the reading circuit 15 is provided above the light-receiving element 10.

The second wiring 72 is a wiring formed using aluminum (Al), copper (Cu), or the like. The second wiring 72 electrically connects the n-type semiconductor region 52 and the reading circuit 15. The second wiring 72 may also be said a portion of the cathode wiring L2 described above. In the first insulating layer 85, the second wiring 72 extends in a stack direction of the first semiconductor layer 81 and second semiconductor layer 91, that is in the Z axis direction. The n-type semiconductor region 52, being a cathode electrode, is electrically connected to the reading circuit 15 via the second wiring 72.

The second insulating layer 95 includes, for example, a conductor film and an insulating film and includes a plurality of wirings and vias. The second insulating layer 95 includes, for example, two or more layers of wirings. For example, the second insulating layer 95 has a configuration where a plurality of wirings is stacked interposing an interlayer insulating layer (interlayer insulating film). Such a layer of the wirings is formed using aluminum (Al), copper (Cu), tungsten (W), polysilicon (Poly-Si), or the like. As an example, the interlayer insulating layer includes a single layer film formed of one type out of silicon oxide (SiO), silicon nitride (SiN), silicon oxynitride (SiON), and the like, or a laminated film formed of two or more types out of them.

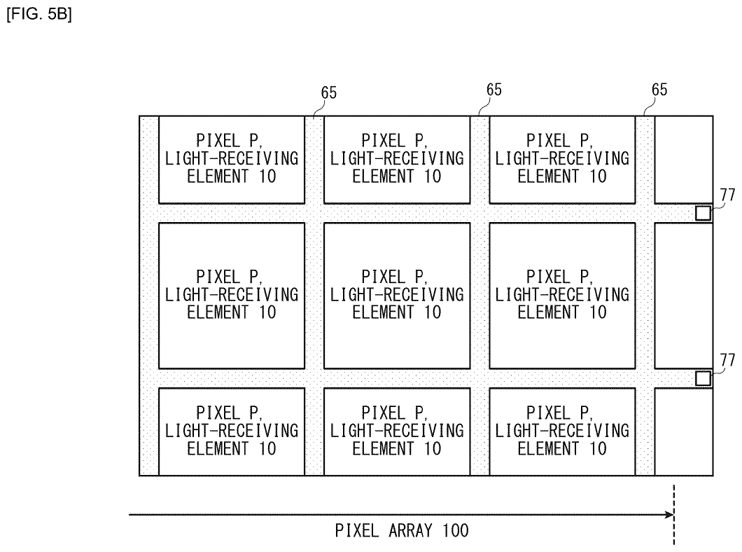

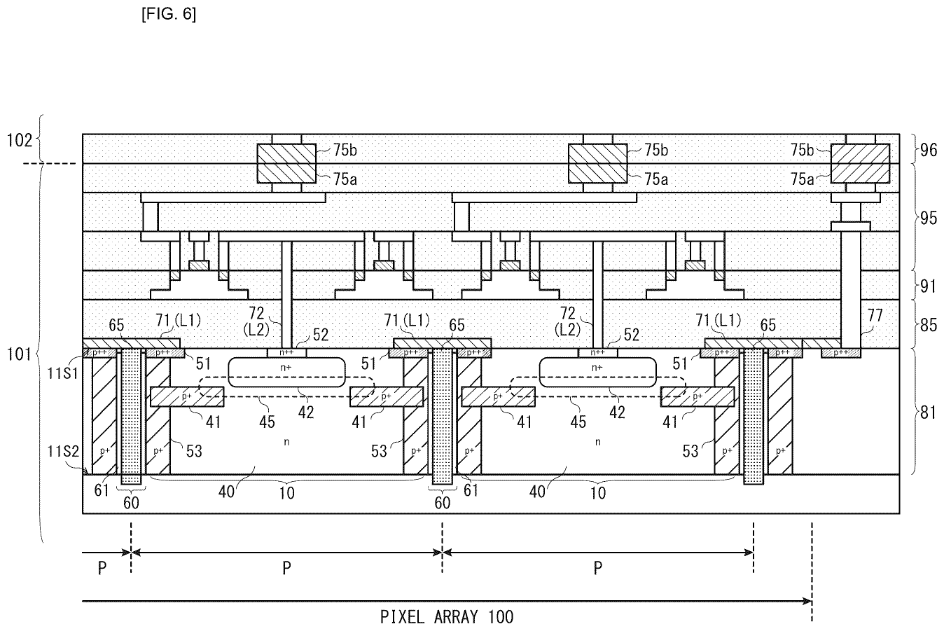

The second insulating layer 95 in the pixel chip 101 is provided with an electrode 75a. Further, an insulating layer 96 in the circuit chip 102 is provided with an electrode 75b. The electrodes 75a and 75b are each an electrode formed using copper (Cu), for example. The electrodes 75a and 75b are provided for each pixel P, for example. For example, a plurality of the electrodes 75a and 75b is arranged side by side, at an interval substantially equal to a pitch of the pixels P (interval of the pixels P) (see FIGS. 5A, 6, or the like to be described below). The electrodes 75a and 75b are each an electrode used for junction between metal electrodes, and thus serve as an electrode for junction.

As an example, with junction between metal electrodes including copper (Cu), that is Cu—Cu junction, the pixel chip 101 and circuit chip 102 are bonded. With the electrodes 75a and 75b, a circuit of the pixel chip 101 and a circuit of the circuit chip 102 are electrically connected to each other. Note that the electrodes 75a and 75b may each include a metal material other than copper, such as nickel (Ni), cobalt (Co), tin (Sn), or gold (Au), for example. Further, the pixel chip 101 and circuit chip 102 may be stacked using a bump.

FIG. 5A is a diagram illustrating an example of a cross-sectional configuration of the photodetection device according to the embodiment. FIG. 5B is a diagram illustrating an example of a plan configuration of the photodetection device according to the embodiment. FIG. 5B illustrates an arrangement example of the light-shielding film 65 on the second surface 11S2 side of the first semiconductor layer 81. The electrodes 75a and 75b have a pitch (an interval at which the electrodes 75a and 75b are arranged) substantially equal to the pixel pitch. The light-shielding film 65 is provided arranged in a grid-like shape on the second surface 11S2 side of the first semiconductor layer 81 as the example illustrated in FIGS. 5A and 5B.

The light-shielding film 65 extends to a region outside the pixel array 100 and is electrically connected to a power supply line, a voltage source, or the like configured to supply a voltage (current). In the example illustrated in FIGS. 5A and 5B, the light-shielding film 65 is wired up to outside the pixel array 100 on the second surface 11S2 side of the first semiconductor layer 81, and is electrically connected, via a wiring 77, to a power supply (voltage source) on the circuit chip 102 side. The wiring 77 includes a through via. Note that, as an example illustrated in FIG. 6, the first wiring 71 may be wired up to outside the pixel array 100 on the first surface 11S1 side of the first semiconductor layer 81, and may be electrically connected, via the wiring 77, to a power supply on the circuit chip 102 side.

In the photodetection device 1 according to the present embodiment, as described above, the first wiring 71 is provided on the first surface 11S1 side of the first semiconductor layer 81. The first wiring 71 is connected to the p-type semiconductor region 51, being an anode electrode of the light-receiving element 10, and to the light-shielding film 65 in the trench 61. This allows the light-shielding film 65 to be used as the anode wiring L1. Thus, a lot of wirings for anode and contacts are possible to be disposed next to the cathode wiring L2, allowing an increase in capacitance added to the cathode wiring L2 to be prevented. The capacitance added to the cathode wiring L2 is possible to be reduced, allowing power consumption to be reduced.

In also a case where the pixel is smaller in size, an increase in capacitance added to the cathode is suppressed, allowing an increase in power consumption to be prevented. Further, in a region stacked on the first surface 11S1 side of the first semiconductor layer 81, an area of a region for a wiring, a transistor, and the like to be disposed is possible to be widened, allowing a reading circuit of wider area and multifunction to be disposed, for example. This makes it possible to achieve the photodetection device 1 of high performance, while preventing an increase in the size of the pixel.

Further, in the present embodiment, the light-shielding film 65 being a metal film with low resistance is used, allowing the anode voltage Va to be supplied to the light-receiving element 10. This allows stable voltage supply to be performed. Moreover, the first wiring 71 includes polycrystalline silicon or amorphous silicon. With this, stacking processing by a heat treatment process with high temperature and forming of an element such as a transistor are possible to be performed for manufacturing of the photodetection device 1 illustrated in FIG. 4A or the like.

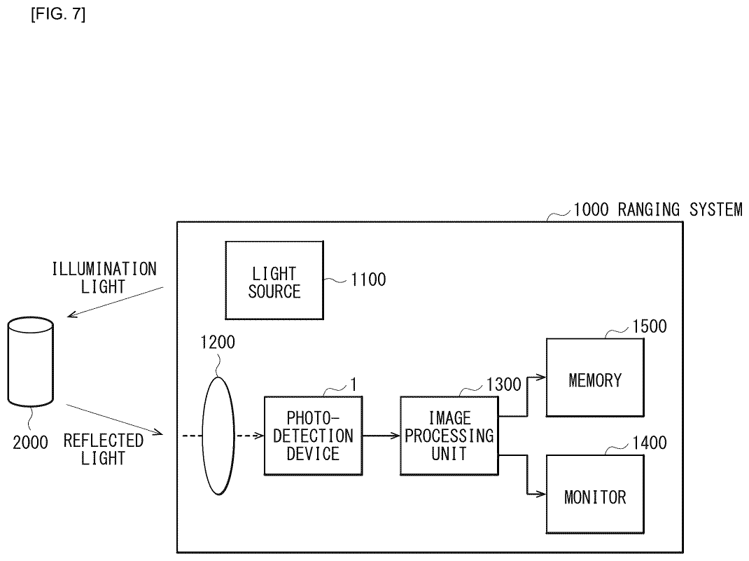

FIG. 7 is a diagram illustrating an example of a schematic configuration of a ranging system according to an embodiment of the present disclosure. A ranging system 1000 (photodetection system) includes the photodetection device 1 described above, a light source 1100, an optical system 1200, an image processing unit 1300, a monitor 1400, and a memory 1500.

The light source 1100 is configured to apply light to a target object. The light source 1100 includes a plurality of light-emitting elements. Examples of the light-emitting elements include LEDs (Light Emitting Diodes) and LDs (Laser Diodes). In the light source 1100, the plurality of light-emitting elements is arranged two-dimensionally in a matrix. The light source 1100 may generate, for example, laser light and output the laser light to the outside.

The optical system 1200 includes one or a plurality of lenses. Image light (incident light) from a target object 2000 is guided by the optical system 1200 to the photodetection device 1 and formed as an image on a light-receiving surface of the photodetection device 1.

The image processing unit 1300, being an image processing circuit, may perform image processing that constructs a distance image on the basis of a signal supplied from the photodetection device 1. The distance image (image data) obtained by the image processing in the image processing unit 1300 may be supplied to and displayed on the monitor 1400 and may be supplied to and stored (recorded) in the memory 1500.

The ranging system 1000 receives light (modulation light or pulse light) applied to the target object 2000 from the light source 1100 and reflected on a surface of the target object 2000, and thus is possible to obtain the distance image depending on a distance to the target object 2000.

### [Workings and Effects]

A photodetection device (photodetection device 1) according to the present embodiment includes: a first semiconductor layer (first semiconductor layer 81) including a light-receiving element (light-receiving element 10) configured to receive light and output a current; a trench (trench 61) provided in the first semiconductor layer, the trench surrounding the light-receiving element; a light-shielding film (light-shielding film 65) provided in the trench, the light-shielding film including a metal material; and a first wiring (first wiring 71) provided on a first surface side of the first semiconductor layer. The light-receiving element includes a first semiconductor region of first conductivity type (for example, p-type semiconductor region 51) and a second semiconductor region of second conductivity type (for example, n-type semiconductor region 52) that are provided on the first surface side of the first semiconductor layer. The first wiring includes polycrystalline silicon or amorphous silicon and electrically connects the first semiconductor region and the light-shielding film.

In the photodetection device 1 according to the present embodiment, on the first surface 11S1 side of the first semiconductor layer 81, the first wiring 71 is provided electrically connecting the p-type semiconductor region 51, being an anode electrode, and the light-shielding film 65 in the trench 61. The light-shielding film 65 is possible to be used as an anode wiring, allowing capacitance added to a cathode wiring to be reduced. This makes it possible to reduce power consumption.

Next, modifications of the present disclosure will be described. Hereinafter, a component similar to that in the embodiments described above is denoted by the same reference sign, and the description of the component is omitted as appropriate.

### 2. Modifications

### (2-1. Modification 1)

Although a configuration example of the pixel P is described in the embodiments described above, the configuration of the pixel P is not limited to this. For example, the p-type semiconductor region 51 and the first wiring 71 described above may be provided at a corner (corner portion) of the pixel P.

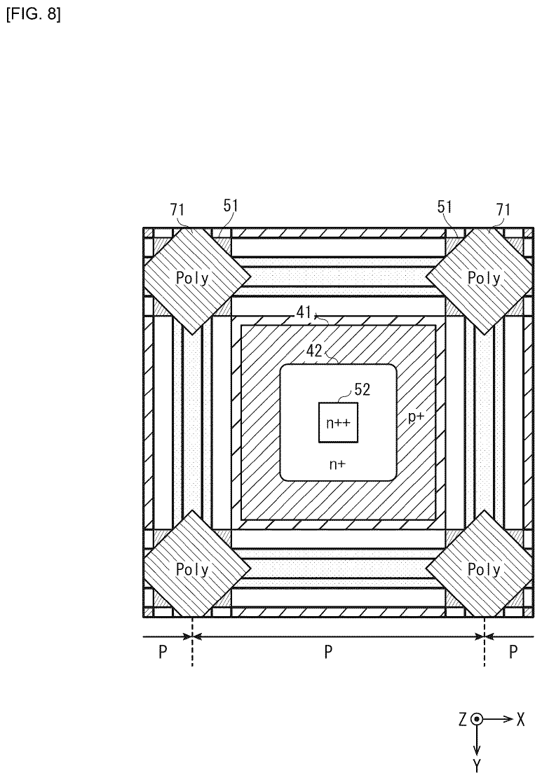

FIG. 8 is a diagram for describing an example of a plan configuration of a pixel of a photodetection device according to Modification 1 of the present disclosure. As the example illustrated in FIG. 8, the p-type semiconductor region 51 and the first wiring 71 may be disposed at four corners of the pixel P. As compared with a case where the p-type semiconductor region 51 is provided at four sides, a dark current due to an intense electric field generated between an anode and cathode is possible to be suppressed.

Note that the p-type semiconductor region 51 and the first wiring 71 may be disposed at only some of the four corners of the pixel P. Further, the shape of each of the p-type semiconductor region 51 and the first wiring 71 is not limited particularly. The shape of each of the p-type semiconductor region 51 and the first wiring 71 may be a rectangular shape as illustrated in FIG. 8, a polygonal shape, an ellipse, or another shape.

### (2-2. Modification 2)

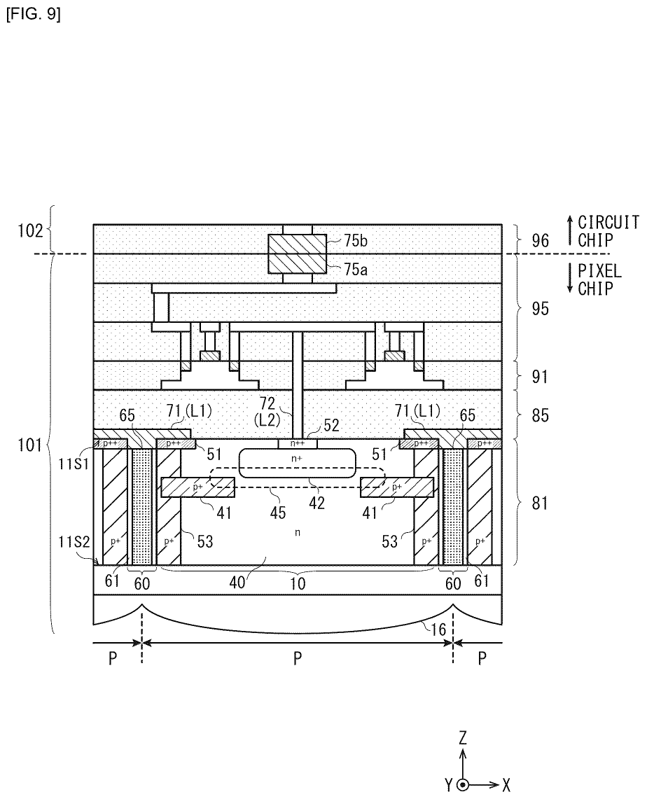

FIG. 9 is a diagram for describing an example of a cross-sectional configuration of a pixel of a photodetection device according to Modification 2. As illustrated in FIG. 9, a portion of the first wiring 71 is formed embedded in the first semiconductor layer 81 and connects a side surface of the p-type semiconductor region 51 and the light-shielding film 65. Further, a top surface of the p-type semiconductor region 51 and the light-shielding film 65 are also connected to each other by the first wiring 71. In the present modification, a contact area of the first wiring 71 and the p-type semiconductor region 51 is possible to be widened, allowing a contact resistance in an anode to be reduced.

### (2-3. Modification 3)

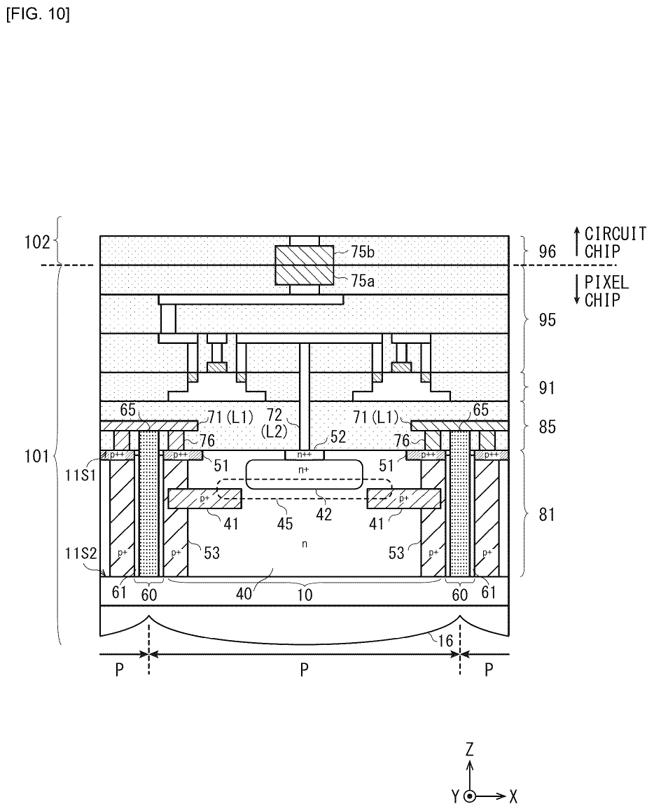

FIG. 10 is a diagram for describing an example of a cross-sectional configuration of a pixel of a photodetection device according to Modification 3. In the example illustrated in FIG. 10, the photodetection device 1 includes a plurality of vias 76. Each via 76 is provided in the first insulating layer 85 and connects the first wiring 71 and the p-type semiconductor region 51. The via 76 includes polycrystalline silicon or amorphous silicon. The p-type semiconductor region 51 is electrically connected to the first wiring 71 via the via 76.

Further, as illustrated in FIG. 10, the light-shielding film 65 reaches the first wiring 71 in the first insulating layer 85. The light-shielding film 65 is connected to the first wiring 71 in the first insulating layer 85. With the light-shielding film 65 provided up to the first insulating layer 85, crosstalk (for example, crosstalk due to light emission of the breakdown region 45) between pixels is possible to be suppressed. Note that the number of vias 76 and the arrangement are not limited to the example illustrated, and any modification is possible as appropriate.

### (2-4. Modification 4)

In the embodiments and modifications described above, although a configuration example of the light-receiving element 10 is described, this is only an example, and the configuration of the light-receiving element 10 is not limited to the example described above. For the configuration of each of the light-receiving element 10 and the breakdown region, any modification is possible as appropriate. As the example illustrated, the breakdown region may be formed by a fringe electric field, or the breakdown region may be formed by disposing the p-type semiconductor region 41 and n-type semiconductor region 42 opposed to each other in a vertical direction. For example, in FIG. 4A, the p-type semiconductor region 41 may be provided on the whole bottom surface of the n-type semiconductor region 42.

### 3. Examples of Use

The photodetection device 1 described above is possible to be used for various cases of sensing light such as visible light, infrared light, ultraviolet light, or X-ray as follows, for example.
Devices that capture images used for viewing, such as digital cameras or mobile devices with camera functions
Devices used for traffic for safe driving such as automatic stop, recognition of the condition of driver, etc., such as: in-vehicle sensors that capture an image of an environment in front of, at the rear of, and around automobile, the interior of the automobile, etc.; surveillance cameras that monitor traveling vehicles or road; or ranging sensors that measure the distance between vehicles, etc.
Devices used in home appliances such as TVs, refrigerators, or air conditioners to capture an image of user's gesture and perform operations according to the gesture
Devices used for medical and healthcare, such as endoscopes or devices that perform angiography by receiving infrared light
Devices used for security, such as surveillance cameras for crime prevention or cameras for personal authentication
Devices used for beauty, such as skin measuring devices that capture an image of the skin or microscopes that capture the image of the scalp
Devices used for sports such as action cameras or wearable cameras for sporting use, etc.
Devices used for agriculture, such as cameras for monitoring the condition of fields and crops

### 4. Applications

### (Application to Mobile Object)

A technique according to the present disclosure (present technique) is possible to be applied to various products. For example, a technique according to the present disclosure may be implemented as a device mounted on any type of mobile objects such as vehicles, electric vehicles, hybrid electric vehicles, motorcycles, bicycles, personal mobilities, airplanes, drones, ships, or robots.

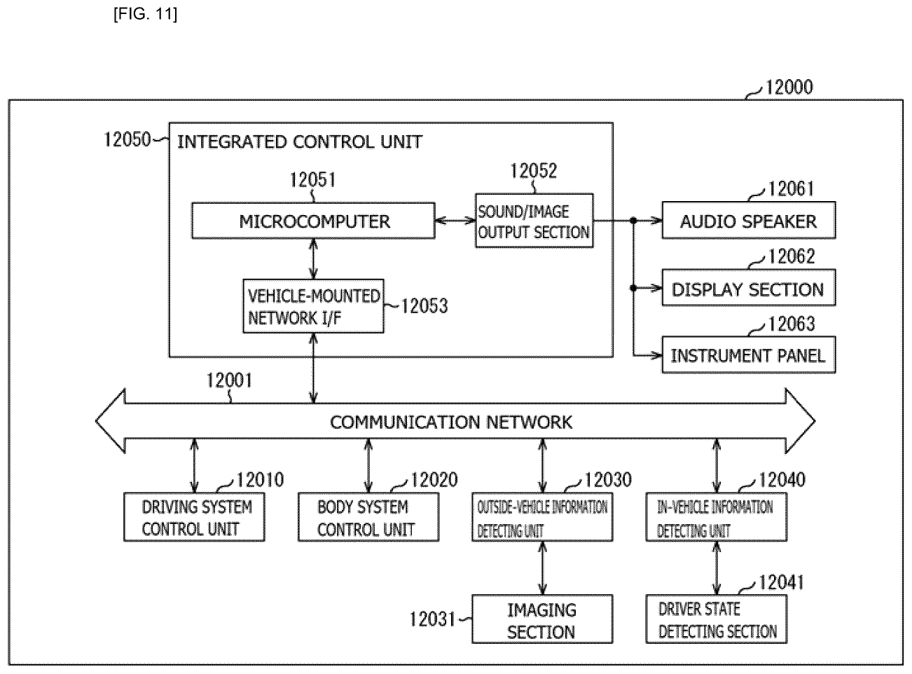

FIG. 11 is a block diagram depicting an example of schematic configuration of a vehicle control system as an example of a mobile body control system to which the technology according to an embodiment of the present disclosure can be applied.

The vehicle control system 12000 includes a plurality of electronic control units connected to each other via a communication network 12001. In the example depicted in FIG. 11, the vehicle control system 12000 includes a driving system control unit 12010, a body system control unit 12020, an outside-vehicle information detecting unit 12030, an in-vehicle information detecting unit 12040, and an integrated control unit 12050. In addition, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automated driving, which makes the vehicle to travel automatedly without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

In addition, the microcomputer 12051 can output a control command to the body system control unit 12020 on the basis of the information about the outside of the vehicle which information is obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 11, an audio speaker 12061, a display section 12062, and an instrument panel 12063 are illustrated as the output device. The display section 12062 may, for example, include at least one of an on-board display and a head-up display.

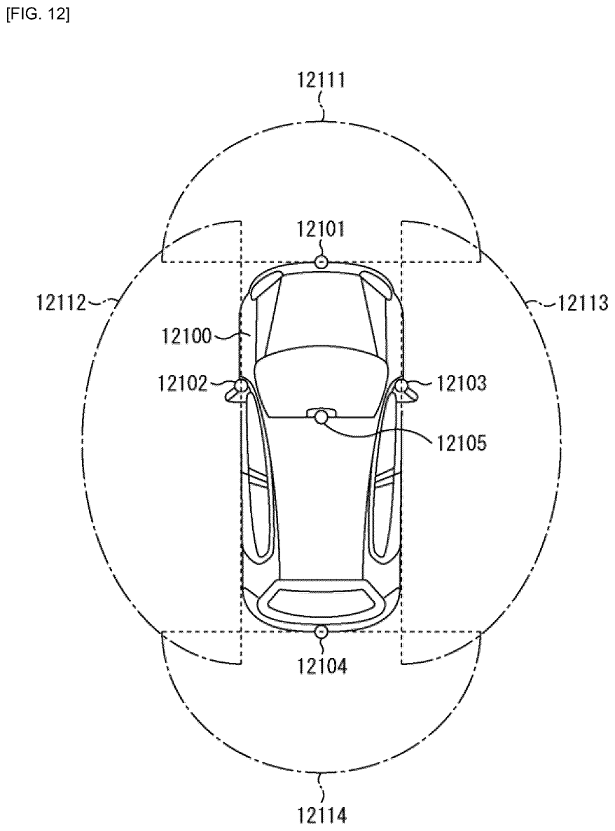

FIG. 12 is a diagram depicting an example of the installation position of the imaging section 12031.

In FIG. 12, the imaging section 12031 includes imaging sections 12101, 12102, 12103, 12104, and 12105.

The imaging sections 12101, 12102, 12103, 12104, and 12105 are, for example, disposed at positions on a front nose, sideview mirrors, a rear bumper, and a back door of the vehicle 12100 as well as a position on an upper portion of a windshield within the interior of the vehicle. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The imaging section 12105 provided to the upper portion of the windshield within the interior of the vehicle is used mainly to detect a preceding vehicle, a pedestrian, an obstacle, a signal, a traffic sign, a lane, or the like.

Incidentally, FIG. 12 depicts an example of photographing ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automated driving that makes the vehicle travel automatedly without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

An example of the mobile body control system to which a technique according to the present disclosure may be applied has been described above. A technique according to the present disclosure may be applied to, for example, the imaging section 12031 in the configuration described above. Specifically, for example, the photodetection device 1 is possible to be applied to the imaging section 12031. Applying a technique according to the present disclosure to the imaging section 12031 allows a captured image in high definition to be obtained and control with high accuracy using the captured image to be performed in the mobile body control system.

### (Application to Endoscopic Surgery System)

A technique according to the present disclosure (present technique) is possible to be applied to various products. For example, a technique according to the present disclosure may be applied to an endoscopic surgery system.

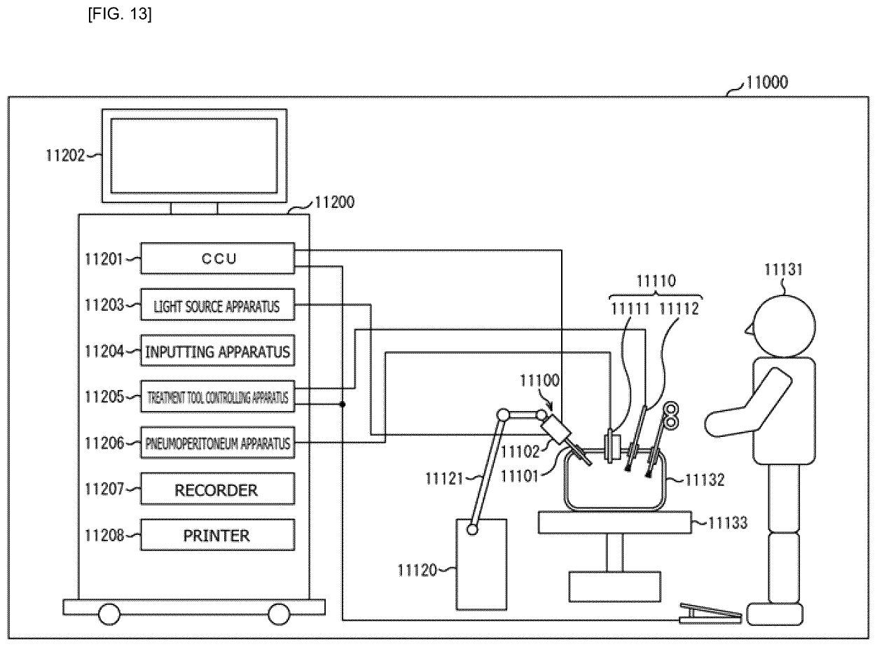

FIG. 13 is a view depicting an example of a schematic configuration of an endoscopic surgery system to which the technology according to an embodiment of the present disclosure (present technology) can be applied.

In FIG. 13, a state is illustrated in which a surgeon (medical doctor) 11131 is using an endoscopic surgery system 11000 to perform surgery for a patient 11132 on a patient bed 11133. As depicted, the endoscopic surgery system 11000 includes an endoscope 11100, other surgical tools 11110 such as a pneumoperitoneum tube 11111 and an energy device 11112, a supporting arm apparatus 11120 which supports the endoscope 11100 thereon, and a cart 11200 on which various apparatus for endoscopic surgery are mounted.

The endoscope 11100 includes a lens barrel 11101 having a region of a predetermined length from a distal end thereof to be inserted into a body cavity of the patient 11132, and a camera head 11102 connected to a proximal end of the lens barrel 11101. In the example depicted, the endoscope 11100 is depicted which includes as a rigid endoscope having the lens barrel 11101 of the hard type. However, the endoscope 11100 may otherwise be included as a flexible endoscope having the lens barrel 11101 of the flexible type.

The lens barrel 11101 has, at a distal end thereof, an opening in which an objective lens is fitted. A light source apparatus 11203 is connected to the endoscope 11100 such that light generated by the light source apparatus 11203 is introduced to a distal end of the lens barrel 11101 by a light guide extending in the inside of the lens barrel 11101 and is irradiated toward an observation target in a body cavity of the patient 11132 through the objective lens. It is to be noted that the endoscope 11100 may be a forward-viewing endoscope or may be an oblique-viewing endoscope or a side-viewing endoscope.

An optical system and an image pickup element are provided in the inside of the camera head 11102 such that reflected light (observation light) from the observation target is condensed on the image pickup element by the optical system. The observation light is photo-electrically converted by the image pickup element to generate an electric signal corresponding to the observation light, namely, an image signal corresponding to an observation image. The image signal is transmitted as RAW data to a CCU 11201.

The CCU 11201 includes a central processing unit (CPU), a graphics processing unit (GPU) or the like and integrally controls operation of the endoscope 11100 and a display apparatus 11202. Further, the CCU 11201 receives an image signal from the camera head 11102 and performs, for the image signal, various image processes for displaying an image based on the image signal such as, for example, a development process (demosaic process).

The display apparatus 11202 displays thereon an image based on an image signal, for which the image processes have been performed by the CCU 11201, under the control of the CCU 11201.

The light source apparatus 11203 includes a light source such as, for example, a light emitting diode (LED) and supplies irradiation light upon imaging of a surgical region to the endoscope 11100.

An inputting apparatus 11204 is an input interface for the endoscopic surgery system 11000. A user can perform inputting of various kinds of information or instruction inputting to the endoscopic surgery system 11000 through the inputting apparatus 11204. For example, the user would input an instruction or a like to change an image pickup condition (type of irradiation light, magnification, focal distance or the like) by the endoscope 11100.

A treatment tool controlling apparatus 11205 controls driving of the energy device 11112 for cautery or incision of a tissue, sealing of a blood vessel or the like. A pneumoperitoneum apparatus 11206 feeds gas into a body cavity of the patient 11132 through the pneumoperitoneum tube 11111 to inflate the body cavity in order to secure the field of view of the endoscope 11100 and secure the working space for the surgeon. A recorder 11207 is an apparatus capable of recording various kinds of information relating to surgery. A printer 11208 is an apparatus capable of printing various kinds of information relating to surgery in various forms such as a text, an image or a graph.

It is to be noted that the light source apparatus 11203 which supplies irradiation light when a surgical region is to be imaged to the endoscope 11100 may include a white light source which includes, for example, an LED, a laser light source or a combination of them. Where a white light source includes a combination of red, green, and blue (RGB) laser light sources, since the output intensity and the output timing can be controlled with a high degree of accuracy for each color (each wavelength), adjustment of the white balance of a picked up image can be performed by the light source apparatus 11203. Further, in this case, if laser beams from the respective RGB laser light sources are irradiated time-divisionally on an observation target and driving of the image pickup elements of the camera head 11102 are controlled in synchronism with the irradiation timings. Then images individually corresponding to the R, G and B colors can be also picked up time-divisionally. According to this method, a color image can be obtained even if color filters are not provided for the image pickup element.

Further, the light source apparatus 11203 may be controlled such that the intensity of light to be outputted is changed for each predetermined time. By controlling driving of the image pickup element of the camera head 11102 in synchronism with the timing of the change of the intensity of light to acquire images time-divisionally and synthesizing the images, an image of a high dynamic range free from underexposed blocked up shadows and overexposed highlights can be created.

Further, the light source apparatus 11203 may be configured to supply light of a predetermined wavelength band ready for special light observation. In special light observation, for example, by utilizing the wavelength dependency of absorption of light in a body tissue to irradiate light of a narrow band in comparison with irradiation light upon ordinary observation (namely, white light), narrow band observation (narrow band imaging) of imaging a predetermined tissue such as a blood vessel of a superficial portion of the mucous membrane or the like in a high contrast is performed. Alternatively, in special light observation, fluorescent observation for obtaining an image from fluorescent light generated by irradiation of excitation light may be performed. In fluorescent observation, it is possible to perform observation of fluorescent light from a body tissue by irradiating excitation light on the body tissue (autofluorescence observation) or to obtain a fluorescent light image by locally injecting a reagent such as indocyanine green (ICG) into a body tissue and irradiating excitation light corresponding to a fluorescent light wavelength of the reagent upon the body tissue. The light source apparatus 11203 can be configured to supply such narrow-band light and/or excitation light suitable for special light observation as described above.

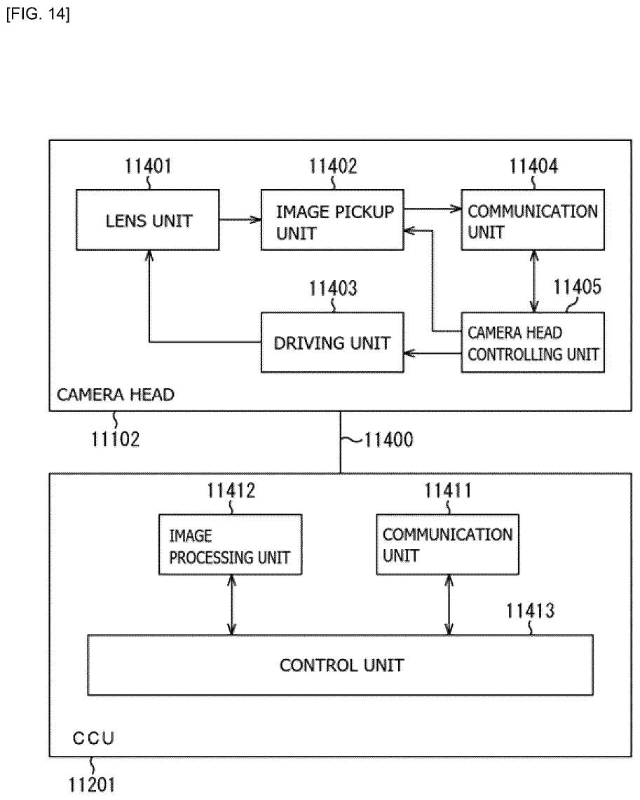

FIG. 14 is a block diagram depicting an example of a functional configuration of the camera head 11102 and the CCU 11201 depicted in FIG. 13.

The camera head 11102 includes a lens unit 11401, an image pickup unit 11402, a driving unit 11403, a communication unit 11404 and a camera head controlling unit 11405. The CCU 11201 includes a communication unit 11411, an image processing unit 11412 and a control unit 11413. The camera head 11102 and the CCU 11201 are connected for communication to each other by a transmission cable 11400.

The lens unit 11401 is an optical system, provided at a connecting location to the lens barrel 11101. Observation light taken in from a distal end of the lens barrel 11101 is guided to the camera head 11102 and introduced into the lens unit 11401. The lens unit 11401 includes a combination of a plurality of lenses including a zoom lens and a focusing lens.

The number of image pickup elements which is included by the image pickup unit 11402 may be one (single-plate type) or a plural number (multi-plate type). Where the image pickup unit 11402 is configured as that of the multi-plate type, for example, image signals corresponding to respective R, G and B are generated by the image pickup elements, and the image signals may be synthesized to obtain a color image. The image pickup unit 11402 may also be configured so as to have a pair of image pickup elements for acquiring respective image signals for the right eye and the left eye ready for three dimensional (3D) display. If 3D display is performed, then the depth of a living body tissue in a surgical region can be comprehended more accurately by the surgeon 11131. It is to be noted that, where the image pickup unit 11402 is configured as that of stereoscopic type, a plurality of systems of lens units 11401 are provided corresponding to the individual image pickup elements.

Further, the image pickup unit 11402 may not necessarily be provided on the camera head 11102. For example, the image pickup unit 11402 may be provided immediately behind the objective lens in the inside of the lens barrel 11101.

The driving unit 11403 includes an actuator and moves the zoom lens and the focusing lens of the lens unit 11401 by a predetermined distance along an optical axis under the control of the camera head controlling unit 11405. Consequently, the magnification and the focal point of a picked up image by the image pickup unit 11402 can be adjusted suitably.

The communication unit 11404 includes a communication apparatus for transmitting and receiving various kinds of information to and from the CCU 11201. The communication unit 11404 transmits an image signal acquired from the image pickup unit 11402 as RAW data to the CCU 11201 through the transmission cable 11400.

In addition, the communication unit 11404 receives a control signal for controlling driving of the camera head 11102 from the CCU 11201 and supplies the control signal to the camera head controlling unit 11405. The control signal includes information relating to image pickup conditions such as, for example, information that a frame rate of a picked up image is designated, information that an exposure value upon image picking up is designated and/or information that a magnification and a focal point of a picked up image are designated.

It is to be noted that the image pickup conditions such as the frame rate, exposure value, magnification or focal point may be designated by the user or may be set automatically by the control unit 11413 of the CCU 11201 on the basis of an acquired image signal. In the latter case, an auto exposure (AE) function, an auto focus (AF) function and an auto white balance (AWB) function are incorporated in the endoscope 11100.

The camera head controlling unit 11405 controls driving of the camera head 11102 on the basis of a control signal from the CCU 11201 received through the communication unit 11404.

The communication unit 11411 includes a communication apparatus for transmitting and receiving various kinds of information to and from the camera head 11102. The communication unit 11411 receives an image signal transmitted thereto from the camera head 11102 through the transmission cable 11400.

Further, the communication unit 11411 transmits a control signal for controlling driving of the camera head 11102 to the camera head 11102. The image signal and the control signal can be transmitted by electrical communication, optical communication or the like.

The image processing unit 11412 performs various image processes for an image signal in the form of RAW data transmitted thereto from the camera head 11102.

The control unit 11413 performs various kinds of control relating to image picking up of a surgical region or the like by the endoscope 11100 and display of a picked up image obtained by image picking up of the surgical region or the like. For example, the control unit 11413 creates a control signal for controlling driving of the camera head 11102.

Further, the control unit 11413 controls, on the basis of an image signal for which image processes have been performed by the image processing unit 11412, the display apparatus 11202 to display a picked up image in which the surgical region or the like is imaged. Thereupon, the control unit 11413 may recognize various objects in the picked up image using various image recognition technologies. For example, the control unit 11413 can recognize a surgical tool such as forceps, a particular living body region, bleeding, mist when the energy device 11112 is used and so forth by detecting the shape, color and so forth of edges of objects included in a picked up image. The control unit 11413 may cause, when it controls the display apparatus 11202 to display a picked up image, various kinds of surgery supporting information to be displayed in an overlapping manner with an image of the surgical region using a result of the recognition. Where surgery supporting information is displayed in an overlapping manner and presented to the surgeon 11131, the burden on the surgeon 11131 can be reduced and the surgeon 11131 can proceed with the surgery with certainty.

The transmission cable 11400 which connects the camera head 11102 and the CCU 11201 to each other is an electric signal cable ready for communication of an electric signal, an optical fiber ready for optical communication or a composite cable ready for both of electrical and optical communications.

Here, while, in the example depicted, communication is performed by wired communication using the transmission cable 11400, the communication between the camera head 11102 and the CCU 11201 may be performed by wireless communication.

An example of the endoscopic surgery system to which a technique according to the present disclosure may be applied has been described above. A technique according to the present disclosure may be suitably applied to, for example, the image pickup unit 11402 provided in the camera head 11102 of the endoscope 11100, among the above-described configurations. Applying a technique according to the present disclosure to the image pickup unit 11402 allows the image pickup unit 11402 to be with high sensitivity, providing the endoscope 11100 with high definition.

While the present disclosure has been described above providing the embodiments, the modifications and the examples of use, and the applications, the present technique is not limited to the embodiments or the like described above and can be modified in various ways. For example, although the modifications described above has been described as a modification of the embodiment described above, the configuration of each modification can be combined as appropriate.

A photodetection device according to one embodiment of the present disclosure includes: a first semiconductor layer including a light-receiving element configured to receive light and output a current; a trench provided in the first semiconductor layer, the trench surrounding the light-receiving element; a light-shielding film provided in the trench, the light-shielding film including a metal material; and a first wiring provided on a first surface side of the first semiconductor layer. The light-receiving element includes a first semiconductor region of first conductivity type and a second semiconductor region of second conductivity type that are provided on the first surface side of the first semiconductor layer. The first wiring includes polycrystalline silicon or amorphous silicon and electrically connects the first semiconductor region and the light-shielding film. With this, the light-shielding film is possible to be used as an anode wiring, allowing capacitance added to a cathode wiring to be reduced. This makes it possible to reduce power consumption.

Note that the effects described herein are merely examples, which are not limited to the description thereof. Another effect may be exhibited. Further, the present disclosure is possible to have configurations as below.

(1)

A photodetection device including:
a first semiconductor layer including a light-receiving element configured to receive light and output a current;
a trench provided in the first semiconductor layer, the trench surrounding the light-receiving element;
a light-shielding film provided in the trench, the light-shielding film including a metal material; and
a first wiring provided on a first surface side of the first semiconductor layer, in which
the light-receiving element includes a first semiconductor region of first conductivity type and a second semiconductor region of second conductivity type that are provided on the first surface side of the first semiconductor layer, and
the first wiring includes polycrystalline silicon or amorphous silicon and electrically connects the first semiconductor region and the light-shielding film.
   (2)

The photodetection device according to (1), in which
the first semiconductor region includes a p-type semiconductor region, and the second semiconductor region includes an n-type semiconductor region.
   (3)

The photodetection device according to (1) or (2), in which the first wiring is provided, on the first surface side of the first semiconductor layer, covering the first semiconductor region and the light-shielding film.

(4)

The photodetection device according to any one of (1) to (3), in which the first wiring is provided surrounding the light-receiving element.

(5)

The photodetection device according to any one of (1) to (4), further including a plurality of pixels each including the light-receiving element, in which
the first semiconductor region is provided at a corner portion of any one of the pixels.
   (6)

The photodetection device according to any one of (1) to (5), further including a plurality of pixels each including the light-receiving element, in which
the first semiconductor region is provided at four corners of any one of the pixels.
   (7)

The photodetection device according to any one of (1) to (6), in which the first wiring is directly connected with the first semiconductor region and the light-shielding film.

(8)

The photodetection device according to any one of (1) to (7), in which a portion of the first wiring is formed embedded in the first semiconductor layer and connects a side surface of the first semiconductor region and the light-shielding film.

(9)

The photodetection device according to any one of (1) to (8), further including an insulating layer provided on the first surface side of the first semiconductor layer, in which
the first wiring is provided in the insulating layer.
   (10)

The photodetection device according to (9), further including a first via that is provided in the insulating layer and that connects the first wiring and the first semiconductor region, in which
the first via includes polycrystalline silicon or amorphous silicon, and
the light-shielding film reaches the first wiring in the insulating layer.
   (11)

The photodetection device according to any one of (1) to (10), in which
the first semiconductor layer includes a first surface and a second surface opposite to the first surface, and
the trench and the light-shielding film reach at least the second surface of the first semiconductor layer.
   (12)

The photodetection device according to any one of (1) to (11), further including a pixel array provided with a plurality of pixels including the light-receiving element, in which
the first wiring extends to a region outside the pixel array.
   (13)

The photodetection device according to any one of (1) to (12), further including:
a reading circuit configured to output a signal based on a current of the light-receiving element; and
a second semiconductor layer stacked on the first semiconductor layer, in which
the second semiconductor layer includes at least a portion of the reading circuit.
   (14)

The photodetection device according to (13), further including:
an insulating layer provided between the first semiconductor layer and the second semiconductor layer; and
a second wiring electrically connecting the second semiconductor region and the reading circuit, in which
the second wiring extends, in the insulating layer, in a stack direction of the first semiconductor layer and the second semiconductor layer.
   (15)

The photodetection device according to (13) or (14), in which
the first wiring is provided in the insulating layer, and
no wiring is provided between the first wiring and the second semiconductor layer.
   (16)

The photodetection device according to any one of (13) to (15), further including:
a first semiconductor chip including the first semiconductor layer and the second semiconductor layer; and
a second semiconductor chip stacked on the first semiconductor chip.
   (17)

The photodetection device according to (16), in which
the first semiconductor chip and the second semiconductor chip are stacked by junction between electrodes, and
the electrodes connecting the first semiconductor chip and the second semiconductor chip have a pitch substantially equal to a pixel pitch.
   (18)

The photodetection device according to any one of (1) to (17), in which the light-receiving element includes a breakdown region allowing avalanche breakdown.

(19)

The photodetection device according to any one of (1) to (18), in which the light-receiving element includes a single photon avalanche diode.

(20)

A ranging system including:
a light source configured to apply light to a target object; and
a photodetection device that receives light from the target object,
in which the photodetection device includes:
   a first semiconductor layer including a light-receiving element configured to receive light and output a current;
   a trench provided in the first semiconductor layer, the trench surrounding the light-receiving element;
   a light-shielding film provided in the trench, the light-shielding film including a metal material; and
   a first wiring provided on a first surface side of the first semiconductor layer,
the light-receiving element includes a first semiconductor region of first conductivity type and a second semiconductor region of second conductivity type that are provided on the first surface side of the first semiconductor layer, and
the first wiring includes polycrystalline silicon or amorphous silicon and electrically connects the first semiconductor region and the light-shielding film.

The present application claims the benefit of Japanese Priority Patent Application JP2022-122172 filed with the Japan Patent Office on Jul. 29, 2022, the entire contents of which are incorporated herein by reference.

It should be understood by those skilled in the art that various modifications, combinations, sub-combinations, and alterations may occur depending on design requirements and other factors insofar as they are within the scope of the appended claims or the equivalents thereof.

1. A photodetection device comprising:
a first semiconductor layer including a light-receiving element configured to receive light and output a current;
a trench provided in the first semiconductor layer, the trench surrounding the light-receiving element;
a light-shielding film provided in the trench, the light-shielding film including a metal material; and
a first wiring provided on a first surface side of the first semiconductor layer,
wherein the light-receiving element includes a first semiconductor region of first conductivity type and a second semiconductor region of second conductivity type that are provided on the first surface side of the first semiconductor layer, and
the first wiring includes polycrystalline silicon or amorphous silicon and electrically connects the first semiconductor region and the light-shielding film.

2. The photodetection device according to claim 1, wherein
the first semiconductor region comprises a p-type semiconductor region, and
the second semiconductor region comprises an n-type semiconductor region.

3. The photodetection device according to claim 1, wherein the first wiring is provided, on the first surface side of the first semiconductor layer, covering the first semiconductor region and the light-shielding film.

4. The photodetection device according to claim 1, wherein the first wiring is provided surrounding the light-receiving element.

5. The photodetection device according to claim 1, further comprising a plurality of pixels each including the light-receiving element, wherein
the first semiconductor region is provided at a corner portion of any one of the pixels.

6. The photodetection device according to claim 1, further comprising a plurality of pixels each including the light-receiving element, wherein
the first semiconductor region is provided at four corners of any one of the pixels.

7. The photodetection device according to claim 1, wherein the first wiring is directly connected with the first semiconductor region and the light-shielding film.

8. The photodetection device according to claim 1, wherein a portion of the first wiring is formed embedded in the first semiconductor layer and connects a side surface of the first semiconductor region and the light-shielding film.

9. The photodetection device according to claim 1, further comprising an insulating layer provided on the first surface side of the first semiconductor layer, wherein
the first wiring is provided in the insulating layer.

10. The photodetection device according to claim 9, further comprising a first via that is provided in the insulating layer and that connects the first wiring and the first semiconductor region, wherein
the first via includes polycrystalline silicon or amorphous silicon, and
the light-shielding film reaches the first wiring in the insulating layer.

11. The photodetection device according to claim 1, wherein
the first semiconductor layer includes a first surface and a second surface opposite to the first surface, and
the trench and the light-shielding film reach at least the second surface of the first semiconductor layer.

12. The photodetection device according to claim 1, further comprising a pixel array provided with a plurality of pixels including the light-receiving element, wherein
the first wiring extends to a region outside the pixel array.

13. The photodetection device according to claim 1, further comprising:
a reading circuit configured to output a signal based on a current of the light-receiving element; and
a second semiconductor layer stacked on the first semiconductor layer, wherein
the second semiconductor layer includes at least a portion of the reading circuit.

14. The photodetection device according to claim 13, further comprising:
an insulating layer provided between the first semiconductor layer and the second semiconductor layer; and
a second wiring electrically connecting the second semiconductor region and the reading circuit, wherein
the second wiring extends, in the insulating layer, in a stack direction of the first semiconductor layer and the second semiconductor layer.

15. The photodetection device according to claim 14, wherein
the first wiring is provided in the insulating layer, and
no wiring is provided between the first wiring and the second semiconductor layer.

16. The photodetection device according to claim 13, further comprising:
a first semiconductor chip including the first semiconductor layer and the second semiconductor layer; and
a second semiconductor chip stacked on the first semiconductor chip.

17. The photodetection device according to claim 16, wherein
the first semiconductor chip and the second semiconductor chip are stacked by junction between electrodes, and
the electrodes connecting the first semiconductor chip and the second semiconductor chip have a pitch substantially equal to a pixel pitch.

18. The photodetection device according to claim 1, wherein the light-receiving element includes a breakdown region allowing avalanche breakdown.

19. The photodetection device according to claim 1, wherein the light-receiving element comprises a single photon avalanche diode.

20. A ranging system comprising:
a light source configured to apply light to a target object; and
a photodetection device that receives light from the target object,
wherein the photodetection device includes
a first semiconductor layer including a light-receiving element configured to receive light and output a current,
a trench provided in the first semiconductor layer, the trench surrounding the light-receiving element,
a light-shielding film provided in the trench, the light-shielding film including a metal material, and
a first wiring provided on a first surface side of the first semiconductor layer,
the light-receiving element includes a first semiconductor region of first conductivity type and a second semiconductor region of second conductivity type that are provided on the first surface side of the first semiconductor layer, and
the first wiring includes polycrystalline silicon or amorphous silicon and electrically connects the first semiconductor region and the light-shielding film.
